(19) United States
(12) Patent Application Publication
(10) Pub. No.: US 2025/0277135 A1
(43) Pub. Date: Sep. 4, 2025

(54) SILANE MODIFICATION OF CERIA NANOPARTICLES IN COLLOIDALLY STABLE SOLUTIONS

(71) Applicant: CMC Materials LLC, Aurora, IL (US)

(72) Inventors: Steven Kraft, Aurora, IL (US); William Ward, Aurora, IL (US); Steven Grumbine, Aurora, IL (US)

(21) Appl. No.: 19/069,717

(22) Filed: Mar. 4, 2025

Related U.S. Application Data
(60) Provisional application No. 63/561,024, filed on Mar. 4, 2024.

(51) Int. Cl. C09G 1/02; B24B 37/04; C09K 3/14; H01L 21/306

(52) U.S. Cl. CPC C09G 1/02; B24B 37/044; C09K 3/1436; H01L 21/30625

(57) ABSTRACT

The invention provides a chemical-mechanical polishing composition comprising (i) ceria abrasive particles, wherein each ceria abrasive particle comprises at least one associated silane comprising at least one moiety of Formula I: Si(R¹)ₙ(X)₍₄₋ₙ₎, wherein R¹, X, and n are as defined herein, and (ii) water. The invention also provides a method of chemically-mechanically polishing a substrate, especially a silicon oxide and/or silicon nitride substrate, by contacting the substrate with the inventive chemical-mechanical polishing composition.

### BACKGROUND OF THE INVENTION

Compositions and methods for planarizing or polishing the surface of a substrate are well known in the art. Polishing compositions (also known as polishing slurries) typically contain an abrasive material in a liquid carrier and are applied to a surface by contacting the surface with a polishing pad saturated with the polishing composition. Typical abrasive materials include silicon dioxide, cerium oxide, aluminum oxide, zirconium oxide, and tin oxide. Polishing compositions are typically used in conjunction with polishing pads (e.g., a polishing cloth or disk). Instead of, or in addition to, being suspended in the polishing composition, the abrasive material may be incorporated into the polishing pad.

Cerium oxide (also referred to as ceria) has been gaining acceptance as an abrasive material for chemical-mechanical polishing (CMP) slurries. While it has been common practice to surface modify abrasive particles such as silica and alumina for use in CMP slurries, the general understanding of ceria CMP slurries suggests that surface modification would block active sites on the surface of ceria particles during CMP resulting in reduction of removal rates.

Thus, there remains a need in the art for polishing compositions comprising ceria abrasive particles and methods of using the same that can provide desirable removal rates and particle size stability.

### BRIEF SUMMARY OF THE INVENTION

The invention provides a chemical-mechanical polishing composition comprising:
(i) ceria abrasive particles, wherein the ceria abrasive particles comprise at least one associated silane comprising at least one moiety of Formula I:

Si(R¹)ₙ(X)₍₄₋ₙ₎ (Formula I),
wherein each R¹ is the same or different and is independently selected from a cationic group,
wherein each X is the same or different and is any oxygen containing substituent, wherein at least one X is associated with a surface atom of the ceria abrasive particle, and
wherein n is 1, 2, or 3, and
(ii) water,
wherein the polishing composition comprises about 0.0005 wt. % to about 25 wt. % of ceria abrasive particles.

The invention also provides a method of chemically mechanically polishing a substrate comprising:
(a) providing a substrate,
(b) providing a polishing pad,
(c) providing a chemical-mechanical polishing composition comprising:
   (i) ceria abrasive particles, wherein the ceria abrasive particles comprise at least one associated silane comprising at least one moiety of Formula I:

Si(R¹)ₙ(X)₍₄₋ₙ₎ (Formula I),
wherein each R¹ is the same or different and is independently selected from a cationic group,
wherein each X is the same or different and is any oxygen containing substituent, wherein at least one X is associated with a surface atom of the ceria abrasive particle,
   and
   wherein n is 1, 2, or 3, and
   (ii) water,
(d) contacting the substrate with the polishing pad and the chemical-mechanical polishing composition, and
(e) moving the polishing pad and the chemical mechanical polishing composition relative to the substrate to abrade at least a portion of the substrate to polish the substrate

### DETAILED DESCRIPTION OF THE INVENTION

The invention provides a chemical-mechanical polishing composition comprising:
(i) ceria abrasive particles, wherein the ceria abrasive particles comprise at least one associated silane comprising at least one moiety of Formula I:

Si(R¹)ₙ(X)₍₄₋ₙ₎ (Formula I),
wherein each R¹ is the same or different and is independently selected from a cationic group,
wherein each X is the same or different and is any oxygen containing substituent, wherein at least one X is associated with a surface atom of the ceria abrasive particle, and
wherein n is 1, 2, or 3, and
(ii) water,
wherein the polishing composition comprises about 0.0005 wt. % to about 25 wt. % of ceria abrasive particles.

The chemical-mechanical polishing composition comprises abrasive particles, wherein the abrasive particles comprise, consist essentially of, or consist of ceria abrasive particles.

As known to one of ordinary skill in the art, ceria is an oxide of the rare earth metal cerium, and is also known as ceric oxide, cerium oxide (e.g., cerium (IV) oxide), or cerium dioxide. Cerium (IV) oxide (CeO₂) can be formed by calcining cerium oxalate or cerium hydroxide. Cerium also forms cerium (III) oxides such as, for example, Ce₂O₃. The ceria abrasive particles can be any one or more of these or other oxides of ceria. It is known that cerium (IV) can coexist with cerium (III) in a mixed oxidation state of and on a cerium particle.

The ceria abrasive particles can be any suitable type of ceria. In an embodiment, the ceria is a wet-process ceria. As used herein, “wet-process” ceria refers to a ceria prepared by a precipitation, condensation-polymerization, or similar process (as opposed to, for example, fumed or pyrogenic ceria). A polishing composition of the invention comprising wet-process ceria abrasive particles has been found to exhibit low defects when used to polish substrates according to a method of the invention. Without wishing to be bound by any particular theory, it is believed that wet-process ceria result in low substrate defectivity when used in the inventive method. An illustrative wet-process ceria is HC-60™ ceria, commercially available from Solvay.

In another embodiment, the polishing composition contains abrasive particles including cubiform ceria abrasive particles suspended in a liquid carrier. By “cubiform” it is meant that the ceria abrasive particles are in the form of a cube, i.e., substantially cubic. Stated another way, the cubiform ceria abrasive particles are cubic in form or nature. However, it will be understood that the edge dimensions, corners, and corner angles need not be exactly or precisely those of a perfect cube. For example, the cubiform ceria abrasive particles may have slightly rounded or chipped corners, slightly rounded edges, edge dimensions that are not exactly equal to one another, corner angles that are not exactly 90 degrees, and/or other minor irregularities and still retain the basic form of a cube. One of ordinary skill in the art will readily be able to recognize (e.g., via scanning electron microscopy or transmission electron microscopy) that the cubiform ceria abrasive particles are cubic in form with tolerances generally allowed for particle growth and deagglomeration.

In another embodiment, the ceria abrasive particles can comprise calcined ceria. Calcined ceria can be prepared by mixing a diluent with a cerium oxide precursor, milling the resulting mixture and calcining the milled mixture at a temperature of 500° C. to 1200° C. to form secondary particles. The cerium oxide precursor can be a hydroxide, carbonate, nitrate, chloride, acetate, hydrate, alkoxide, or sulfide salt of cerium, and the diluent can be K₂CO₃, NaCl, CaCl₂, MgCl₂, Na₂SO₄, Na₂CO₃, Ca(OH)₂, KCl, or K₂SO₄. The calcined powder obtained by this procedure can be washed with distilled water to remove the diluent.

The polishing composition can comprise ceria abrasive particles selected from wet-process ceria, calcined ceria, and combinations thereof.

The polishing composition can comprise any suitable amount of ceria abrasive particles. Typically, the polishing composition comprises about 0.1 wt. % or more of ceria abrasive particles, e.g., about 0.2 wt. % or more, about 0.3 wt. % or more, about 0.4 wt. % or more, about 0.5 wt. % or more, about 0.6 wt. % or more, about 0.7 wt. % or more, about 0.8 wt. % or more, about 0.9 wt. % or more, about 1 wt. % or more, about 2 wt. % or more, about 3 wt. % or more, about 4 wt. % or more, or about 5 wt. % or more. Alternatively, or in addition, the polishing composition comprises about 20 wt. % or less of ceria abrasive particles, e.g., about 15 wt. % or less, about 10 wt. % or less, about 9 wt. % or less, about 5 wt. % or less, about 3 wt. % or less, about 2 wt. % or less, or about 1 wt. % or less. Thus, the polishing composition can comprise ceria abrasive particles in an amount bounded by any two of the aforementioned endpoints. For example, the polishing composition can comprise about 0.1 wt. % to about 20 wt. % of ceria abrasive particles, e.g., about 0.1 wt. % to about 19 wt. %, about 0.1 wt. % to about 18 wt. %, about 0.1 wt. % to about 17 wt. %, about 0.1 wt. % to about 16 wt. %, about 0.1 wt. % to about 15 wt. %, about 0.1 wt. % to about 14 wt. %, about 0.1 wt. % to about 13 wt. %, about 0.1 wt. % to about 12 wt. %, about 0.1 wt. % to about 11 wt. %, about 0.1 wt. % to about 10 wt. %, about 0.5 wt. % to about 9 wt. %, about 0.5 wt. % to about 8 wt. %, about 0.5 wt. % to about 7 wt. %, about 0.5 wt. % to about 6 wt. %, or about 0.5 wt. % to about 5 wt. %, and more preferably about 0.1 to about 2% or 0.2 to about 1%.

The ceria abrasive particles comprising at least one associated silane comprising at least one moiety of Formula I can have any suitable average size (i.e., average particle diameter). If the average ceria abrasive particle size is too small, the polishing composition may not exhibit sufficient removal rate. In contrast, if the average ceria abrasive particle size is too large, the polishing composition may exhibit undesirable polishing performance such as, for example, poor substrate defectivity. Accordingly, the ceria abrasive particles can have an average particle size of about 10 nm or more, for example, about 15 nm or more, about 20 nm or more, about 25 nm or more, about 30 nm or more, about 35 nm or more, about 40 nm or more, about 45 nm or more, or about 50 nm or more. Alternatively, or in addition, the ceria abrasive particles can have an average particle size of about 1,000 nm or less, for example, about 750 nm or less, about 500 nm or less, about 250 nm or less, about 150 nm or less, about 100 nm or less, about 75 nm or less, or about 50 nm or less. Thus, the ceria abrasive particles can have an average particle size bounded by any two of the aforementioned endpoints. For example, the ceria abrasive particles can have an average particle size of about 10 nm to about 1,000 nm, e.g., about 10 nm to about 750 nm, about 15 nm to about 500 nm, about 20 nm to about 250 nm, about 20 nm to about 150 nm, about 25 nm to about 150 nm, about 25 nm to about 100 nm, about 50 nm to about 150 nm, or about 50 nm to about 100 nm. For spherical ceria abrasive particles, the size of the particle is the diameter of the particle. For non-spherical ceria abrasive particles, the size of the particle is the diameter of the smallest sphere that encompasses the particle. The particle size of the ceria abrasive particles can be measured using any suitable technique, for example, using laser diffraction techniques. Suitable particle size measurement instruments are available from, for example, Malvern Instruments (Malvern, UK). Other suitable particle size measurement techniques include SEM and TEM, which are well known to those of skill in the art.

In some embodiments, the ceria abrasive particles of the polishing composition exhibit a multimodal particle size distribution. As used herein, the term “multimodal” means that the ceria abrasive particles exhibit an average particle size distribution having at least 2 maxima (e.g., 2 or more maxima, 3 or more maxima, 4 or more maxima, or 5 or more maxima). Preferably, in these embodiments, the ceria abrasive particles exhibit a bimodal particle size distribution, i.e., the ceria abrasive particles exhibit a particle size distribution having 2 average particle size maxima. The terms “maximum” and “maxima” mean a peak or peaks in the particle size distribution. The peak or peaks correspond to the average particle sizes described herein for the ceria abrasive particles. Thus, for example, a plot of the number of particles versus particle size will reflect a bimodal particle size distribution, with a first peak in the particle size range of about 75 nm to about 150 nm (for example, about 80 nm to about 140 nm, about 85 nm to about 130 nm, or about 90 nm to about 120 nm), and a second peak in the particle size range of about 25 nm to about 70 nm (for example, about 30 nm to about 65 nm, about 35 nm to about 65 nm, or about 40 nm to about 60 nm). The ceria abrasive particles having a multimodal particle size distribution can be obtained by combining two different types of ceria abrasive particles each having a monomodal particle size distribution.

The abrasive preferably is colloidally stable. The term colloid refers to the suspension of abrasive particles in the liquid carrier. Colloidal stability refers to the maintenance of that suspension through time. In the context of the invention, an abrasive is considered colloidally stable if, when the abrasive is placed into a 100 ml graduated cylinder and allowed to stand unagitated for a time of 2 hours, the difference between the concentration of particles in the bottom 50 ml of the graduated cylinder ([B] in terms of g/ml) and the concentration of particles in the top 50 ml of the graduated cylinder ([T] in terms of g/ml) divided by the initial concentration of particles in the abrasive composition ([C] in terms of g/ml) is less than or equal to 0.5 (i.e., {[B]-[T]}/[C]≤0.5). More preferably, the value of [B]-[T]/[C] is less than or equal to 0.3, and most preferably is less than or equal to 0.1.

The ceria abrasive particles can have any suitable average number of silicon atoms per nm² of ceria particles. The ceria abrasive particles can have an average number of silicon atoms per nm² of surface area of the ceria abrasive particles of about 0.08 atoms per nm² or more, e.g., about 0.10 atoms per nm² or more, about 0.12 atoms per nm² or more, about 0.14 atoms per nm² or more, about 0.16 atoms per nm² or more, about 0.18 atoms per nm² or more, or about 0.20 atoms per nm² or more. Alternatively, or in addition, the ceria abrasive particles can have an average number of silicon atoms per nm² of surface area of the ceria abrasive particles of about 5 atoms per nm² or less, e.g., about 4.5 atoms per nm² or less, about 4 atoms per nm² or less, about 3.5 atoms per nm² or less, about 3 atoms per nm² or less, about 2.5 atoms per nm² or less, about 2 atoms per nm² or less, about 1.5 atoms per nm² or less, about 1 atoms per nm² or less, or about 0.8 atoms per nm² or less. Thus, the ceria abrasive particles can have any suitable average number of silicon atoms per nm² of surface area of the ceria abrasive particles bounded by any two of the aforementioned endpoints. For example, the ceria abrasive particles can have an average number of silicon atoms per nm² of ceria abrasive particles of about 0.08 to about 5 atoms per nm², about 0.10 to about 4.5 atoms per nm², about 0.12 to about 4 atoms per nm², about 0.14 to about 3.5 atoms per nm², about 0.16 to about 3.5 atoms per nm², about 0.18 to about 3 atoms per nm², about 0.20 to about 3 atoms per nm², about 0.20 to about 2.5 atoms per nm², about 0.20 to about 2 atoms per nm², about 0.20 to about 1.5 atoms per nm², about 0.20 to about 1 atoms per nm², or about 0.20 to about 0.8 atoms per nm². In an embodiment, the surface area of the ceria abrasive particles can be determined by use of the Brunauer-Emmett-Teller (BET) N₂ adsorption method, as well known by those of ordinary skill in the art.

The surface coverage of the ceria abrasive particles can be determined using any suitable method. In an embodiment, the measured surface area (as from BET measurements) and literature values of surface hydroxyls per unit of surface area allows for calculation of total number of silane molecules needed at 100% coverage. Using a known amount of silane for surface treatment of the ceria abrasive particles, followed by separation of the surface treated ceria abrasive particles from the treatment medium (known as the supernatant) and then determination of unreacted silane in the separated treatment medium by ICP, allows determination of % surface coverage (e.g., surface modification). For example, a sample of treated ceria can be centrifuged at 30,000 rpm for 30 minutes, followed by careful removal of a small amount of supernatant from the top of the centrifuge tube. The supernatant sample is then analyzed by ICP to determine the Si content. This value can be used to determine the efficiency silane surface coverage on the particle. In another example, the amount of silicon atoms on the ceria particles can be determined by dissolution of the ceria particles following centrifugation, followed by ICP of the resulting solution and then dividing the atoms of Si by the BET measured surface area.

The ceria abrasive particles can have any suitable surface coverage, expressed as a percentage of the surface hydroxyls of the ceria abrasive particles per unit of surface area. The ceria abrasive particles can have a percent surface coverage of the ceria abrasive particles of about 1% or more, e.g., about 2% or more, about 3% or more, about 4% or more, about 5% or more, about 10% or more, about 15% or more, about 20% or more, about 25% or more, or about 30% or more. Alternatively, or in addition, the ceria abrasive particles can have a percent surface coverage of the ceria abrasive particles of about 100% or less, e.g., about 90% or less, about 80% or less, about 70% or less, about 60% or less, about 2.5 atoms per nm² or less, or about 50% or less. Thus, the ceria abrasive particles can have any suitable percent surface coverage of the ceria abrasive particles bounded by any two of the aforementioned endpoints. For example, the ceria abrasive particles can have percent surface coverage of the ceria abrasive particles of about 1% to about 100%, about 2% to about 90%, about 3% to about 80%, about 4% to about 70%, about 5% to about 60%, or about 10% to about 50%.

The ceria abrasive particles comprise at least one associated silane of Formula (I):

Si(R¹)ₙ(X)₍₄₋ₙ₎ (Formula I),

wherein each R¹ is the same or different and is selected from a cationic group, wherein each X is the same or different and is any oxygen containing substituent, wherein at least one X is associated with a surface atom of the ceria abrasive particle and wherein n is 1, 2, or 3. For example, X is the same or different, is any suitable substituent, and is independently selected from hydroxyl, halide, and alkoxy. In some embodiments, Formula 1 can be derived from silanes which have any suitable group that is reactive to hydrolysis and allows association of the silane with any suitable atom of the ceria particles. For example, by formation of covalent bonds between the silicon and a surface atom of the ceria particles, such as oxygen. In some other embodiments, X can represent a bond between the silica atom of the silane and the ceria particles, for example, at least one X can be —O-G- wherein G is a surface ceria atom. Non-limiting examples of suitable X groups include C₁-C₁₀ alkoxy (e.g., methoxy, ethoxy, propoxy, isopropoxy, butoxy, and the like), halo (e.g., fluoro, chloro, and bromo), or sulfonate (e.g., methanesulfonate, benzenesulfonate, p-toluenesulfonate, trifluoromethanesulfonate, and the like).

Typically, the silane has a molecular weight of about 1500 Daltons or less, e.g., about 1400 Daltons or less, about 1300 Daltons or less, about 1200 Daltons or less, about 1100 Daltons or less, about 1000 Daltons or less, about 900 Daltons or less, about 800 Daltons or less, about 700 Daltons or less, about 600 Daltons or less, about 500 Daltons or less, about 400 Daltons or less, or about 300 Daltons or less.

R¹ can be any suitable cationic group. In some embodiments, at least one R¹ is a cationic group, wherein the group is selected from an amine (primary, secondary, tertiary, and quaternary), monoamine, diamine, triamine, polyamine, pyridinium, and combinations thereof. In some embodiments, R¹ can be a cationic group, wherein the cationic group is selected from (3-Aminopropyl)trialkoxysilane, bis(Trialkoxysilylpropyl)amine, 3-trialkoxysilylpropyl)diethylenetriamine, 3-(N-cyclohexylamino)propyltrialkoxysilane, N-Phenyl-gamma-aminopropyltrialkoxysilane, trialkoxysilylpropyl (polyethyleneimine), Aminoethylaminomethyl) phenethyltrialkoxysilane, N-(2-aminoethyl)-3-aminopropyltrialkoxysilane, N-(6-aminohexyl)aminoethyltrialkoxysilane, Bis(2-hydroxyethyl)aminopropyltrialkoxysilane, N-Butylaminopropyltrialkoxysilane, (N,N-Dimethylaminopropyl)trialkoxysilane, N(aminoethyl)aminopropyltrialkoxysilane, N-[3-(Trialkoxysilyl)propyl]-N,N,N-trialkylammonium halide, 2-(4-pyridylethyl)trialkoxysilane and combinations thereof.

As used herein, “alkyl” groups include straight-chain, branched and cyclic alkyl groups. Alkyl groups include those having from 1 to 30 carbon atoms. Alkyl groups include small alkyl groups having 1 to 3 carbon atoms. Alkyl groups include medium length alkyl groups having from 4-10 carbon atoms. Alkyl groups include long alkyl groups having more than 10 carbon atoms, particularly those having 10-30 carbon atoms. Alkyl groups are optionally substituted. Substituted alkyl groups include among others those which are substituted with aryl groups, which in turn can be optionally substituted. Specific alkyl groups include methyl, ethyl, n-propyl, iso-propyl, cyclopropyl, n-butyl, s-butyl, t-butyl, cyclobutyl, n-pentyl, branched-pentyl, cyclopentyl, n-hexyl, branched hexyl, and cyclohexyl groups, all of which are optionally substituted. Substituted alkyl groups include fully halogenated or semihalogenated alkyl groups, such as alkyl groups having one or more hydrogens replaced with one or more fluorine atoms, chlorine atoms, bromine atoms and/or iodine atoms. Substituted alkyl groups include fully fluorinated or semifluorinated alkyl groups, such as alkyl groups having one or more hydrogens replaced with one or more fluorine atoms. An alkoxy group is an alkyl group that has been modified by linkage to oxygen and can be represented by the formula R—O and can also be referred to as an alkyl ether group. Examples of alkoxy groups include, but are not limited to, methoxy, ethoxy, propoxy, butoxy and heptoxy. Alkoxy groups include substituted alkoxy groups wherein the alky portion of the groups is substituted as provided herein in connection with the description of alkyl groups. As used herein MeO— refers to CH₃O—.

The inventive polishing compositions comprise ceria particles that are modified to comprise one or more silane compounds comprising at least one moiety of Formula I, as described herein. In accordance with the invention, the one or more silane compounds are bound to the ceria particles, e.g., covalently bound to the ceria particles, adsorbed by the ceria particles, or subject to Van der Waals interactions with the ceria particles. As used herein, “permanently bound” means that the bound silane is not removed from the ceria abrasive particles under conditions that typically separate a silane compound non-permanently associated with a metal oxide particle. For example, the silane modified ceria particles of the invention can be subjected to ultrafiltration, ion-exchange, or multiple washings, and can be isolated from these conditions, while still comprising at least one bound silane comprising at least one moiety of Formula I, as described herein. An illustrative process includes, for example, an ultrafiltration method as described in, e.g., U.S. Pat. No. 9,499,721 at col. 11, lines 14-31.

Without wishing to be bound by any particular theory, the silane (e.g., silyl group or silyl moiety) can be attached to the surface of the ceria oxide through one or more covalent bonds, one or more electrostatic bonds (e.g., one or more ionic bonds), one or more hydrogen bonds, one or more Van der Waals bonds, or combinations thereof. In an embodiment, the silyl group is attached to a portion of the surface of the ceria oxide particle through one or more covalent bonds.

The polishing composition comprises water. The water can be any suitable water and can be, for example, deionized water or distilled water. In some embodiments, the polishing composition can further comprise one or more organic solvents in combination with the water. For example, the polishing composition can further comprise a hydroxylic solvent such as methanol or ethanol, a ketonic solvent, an amide solvent, a sulfoxide solvent, and the like. Preferably, the polishing composition comprises pure water.

The polishing composition can have any suitable pH. Typically, the polishing composition can have a pH of about 3 or more, e.g., about 3.2 or more, about 3.4 or more, about 3.6 or more, about 3.8 or more, or about 4 or more. Alternatively, or in addition, the polishing composition can have a pH of about 10 or less, e.g., about 9.5 or less, about 9 or less, about 8.5 or less, or about 8 or less. Thus, the polishing composition can have a pH bounded by any two of the aforementioned endpoints. For example, the polishing composition can have a pH of about 3 to about 10, e.g., about 3 to about 9.5, about 3 to about 9, about 3 to about 8.5, about 3 to about 8, about 4 to about 9, about 4 to about 8, or about 5 to about 10. In an embodiment, the pH of the polishing composition is about 3 to about 8. In another embodiment, the pH of the polishing composition is about 5 to about 10.

The polishing composition, more particularly, the ceria abrasive particles of the polishing composition, can have any suitable zeta potential. Zeta potential of a particle refers to the difference between the electrical charge of the ions surrounding the particle and the electrical charge of the bulk solution (e.g., the liquid carrier and any other components dissolved therein). In an embodiment, the polishing composition has a zeta potential greater than about 20 mV at a pH of about 3 to about 6 or a zeta potential greater than about 10 mV at a pH of about 6 to about 8. In another embodiment, the polishing composition has a zeta potential less than about-5 mV at a pH of about 5 to about 10 or a zeta potential less than about 10 mV at a pH of about 7 to about 10.

The pH of the polishing composition can be adjusted using any suitable acid or base. Non-limiting examples of suitable acids include nitric acid, sulfuric acid, phosphoric acid, and organic acids such as formic acid and acetic acid. Non-limiting examples of suitable bases include sodium hydroxide, potassium hydroxide, and ammonium hydroxide.

The polishing composition optionally further comprises a buffering agent. The buffering agent can be any suitable buffering agent capable of maintaining the polishing composition at a pH as recited herein. Non-limiting examples of suitable buffering agents include formic acid, malonic acid, acetic acid, oxalic acid, citric acid, phosphoric acid, and salts thereof.

The chemical-mechanical polishing composition optionally further comprises one or more additives. Illustrative additives include conditioners (e.g., polymeric conditioning agents), acids (e.g., sulfonic acids, mineral acids, organic acids), complexing agents (e.g., anionic polymeric complexing agents), corrosion inhibitors (e.g., hydroxybenzotriazole, triazoles, etc.), chelating agents (e.g., EDTA), biocides, scale inhibitors (e.g., phosphonic acids), dispersants (e.g., nonionic surfactants), catalysts (e.g., ferric salts), and the like. In an embodiment, the polishing composition comprises an additive selected from a buffer, a surfactant, a catalyst, a stabilizer, a corrosion inhibitor, a biocide, and combinations thereof.

A biocide, when present, can be any suitable biocide and can be present in the polishing composition in any suitable amount. A suitable biocide is an isothiazolinone biocide. The amount of biocide in the polishing composition typically is about 1 ppm to about 500 ppm, preferably about 10 ppm to about 125 ppm.

The polishing composition can be prepared by any suitable technique, many of which are known to those skilled in the art. The polishing composition can be prepared in a batch or continuous process. Generally, the polishing composition can be prepared by combining the components thereof in any order. The term “component” as used herein includes individual ingredients (e.g., ceria abrasive particles, optional acid, optional base, optional buffer, optional surfactant, optional catalyst, optional stabilizer, optional corrosion inhibitor, etc.) as well as any combination of ingredients (e.g., ceria abrasive particles, optional acid, optional base, optional buffer, optional surfactant, optional catalyst, optional stabilizer, optional corrosion inhibitor, etc.).

For example, the ceria abrasive particles can be dispersed in water. The optional acid, optional base, optional buffer, optional surfactant, optional catalyst, optional stabilizer, and optional corrosion inhibitor can then be added and mixed by any method that is capable of incorporating the components into the polishing composition. The polishing composition also can be prepared by mixing the components at the surface of the substrate during the polishing operation.

The polishing composition can be supplied as a one-package system comprising ceria abrasive particles, optional acid, optional base, optional buffer, optional surfactant, optional catalyst, optional stabilizer, optional corrosion inhibitor, and water. Alternatively, the ceria abrasive particles can be supplied as a dispersion in water in a first container, and the optional acid, optional base, optional buffer, optional surfactant, optional catalyst, optional stabilizer, optional corrosion inhibitor can be supplied in a second container, either in dry form, or as a solution or dispersion in water. The components in the first or second container can be in dry form while the components in the other container can be in the form of an aqueous dispersion. Moreover, it is suitable for the components in the first and second containers to have different pH values, or alternatively to have substantially similar, or even equal, pH values. Other two-container, or three or more-container, combinations of the components of the polishing composition are within the knowledge of one of ordinary skill in the art.

The polishing composition of the invention also can be provided as a concentrate which is intended to be diluted with an appropriate amount of water prior to use. In such an embodiment, the polishing composition concentrate can comprise the ceria abrasive particles, optional acid, optional base, optional buffer, optional surfactant, optional catalyst, optional stabilizer, optional corrosion inhibitor and water, in amounts such that, upon dilution of the concentrate with an appropriate amount of water, each component of the polishing composition will be present in the polishing composition in an amount within the appropriate range recited above for each component. For example, the ceria abrasive particles, optional acid, optional base, optional buffer, optional surfactant, optional catalyst, optional stabilizer, optional corrosion inhibitor can each be present in the concentration in an amount that is about 2 times (e.g., about 3 times, about 4 times, or about 5 times) greater than the concentration recited above for each component so that, when the concentrate is diluted with an equal volume of water (e.g., 2 equal volumes of water, 3 equal volumes of water, or 4 equal volumes of water, respectively), each component will be present in the polishing composition in an amount within the ranges set forth above for each component. Furthermore, as will be understood by those of ordinary skill in the art, the concentrate can contain an appropriate fraction of the water present in the final polishing composition in order to ensure that other components are at least partially or fully dissolved in the concentrate.

The invention also provides a method of chemically mechanically polishing a substrate comprising (a) providing a substrate, (b) providing a polishing pad, (c) providing a chemical-mechanical polishing composition comprising (i) ceria abrasive particles, wherein each ceria abrasive particle comprises at least one associated silane comprising at least one moiety of Formula I: Si(R¹)ₙ(X)₍₄₋ₙ₎ wherein each R¹ is the same or different and is selected from a cationic group, wherein each X is the same or different and is any oxygen containing substituent, wherein at least one X is associated with a surface atom of the ceria abrasive particle, wherein n is 1, 2, or 3, and (ii) water, (d) contacting the substrate with the polishing pad and the chemical-mechanical polishing composition, and (e) moving the polishing pad and the chemical mechanical polishing composition relative to the substrate to abrade at least a portion of the substrate to polish the substrate. Preferably, the substrate comprises at least one layer of silicon oxide and/or silicon nitride on a surface of the substrate, and at least a portion of the silicon oxide on a surface of the substrate and/or at least a portion of the silicon nitride on a surface of the substrate is abraded to thereby polish the substrate. In some embodiments, the substrate comprising a dielectric layer (e.g., silicon oxide) further comprises a silicon nitride layer.

In certain embodiments, the substrate comprises polysilicon in combination with silicon oxide and/or silicon nitride. The polysilicon can be any suitable polysilicon, many of which are known in the art. The polysilicon can have any suitable phase and can be amorphous, crystalline, or a combination thereof.

In an embodiment, the dielectric layer comprises silicon oxide. The silicon oxide similarly can be any suitable silicon oxide, many of which are known in the art. Suitable types of silicon oxide include, but are not limited to, borophosphosilicate glass (BPSG), plasma-enhanced tetraethyl orthosilicate (PETEOS), thermal oxide, undoped silicate glass, and high-density plasma (HDP) oxide.

The polishing composition of the invention desirably exhibits a high removal rate when polishing a substrate comprising silicon oxide according to a method of the invention. For example, when polishing silicon wafers comprising silicon oxide in accordance with an embodiment of the invention, such as HDP oxides and/PETEOS and/or tetraethyl orthosilicate (TEOS), the polishing composition desirably exhibits a removal rate of the silicon oxide of about 500 Å/min or higher, e.g., about 550 Å/min or higher, about 600 Å/min or higher, about 650 Å/min or higher, about 700 Å/min or higher, about 750 Å/min or higher, about 800 Å/min or higher, about 850 Å/min or higher, about 900 Å/min or higher, about 950 Å/min or higher, about 1000 Å/min or higher, about 1100 Å/min or higher, about 1200 Å/min or higher, about 1300 Å/min or higher, about 1400 Å/min or higher, about 1500 Å/min or higher, about 1600 Å/min or higher, about 1700 Å/min or higher, about 1800 Å/min or higher, about 1900 Å/min or higher, about 2000 Å/min or higher, about 2100 Å/min or higher, about 2200 Å/min or higher, about 2300 Å/min or higher, about 2400 Å/min or higher, about 2500 Å/min or higher, about 2600 Å/min or higher, about 2700 Å/min or higher, about 2800 Å/min or higher, about 2900 Å/min or higher, about 3000 Å/min or higher, about 3100 Å/min or higher, about 3200 Å/min or higher, about 3300 Å/min or higher, about 3400 Å/min or higher, about 3500 Å/min or higher, about 3600 Å/min or higher, about 3700 Å/min or higher, about 3800 Å/min or higher, about 3900 Å/min or higher, about 4000 Å/min or higher, about 4100 Å/min or higher, about 4200 Å/min or higher, about 4300 Å/min or higher, about 4400 Å/min or higher, about 4500 Å/min or higher, about 4600 Å/min or higher, about 4700 Å/min or higher, about 4800 Å/min or higher, about 4900 Å/min or higher, about 5000 Å/min, about 5100 Å/min or higher, about 5200 Å/min or higher, about 5300 Å/min or higher, about 5400 Å/min or higher, about 5500 Å/min or higher, about 5600 Å/min or higher, about 5700 Å/min or higher, about 5800 Å/min or higher, about 5900 Å/min or higher, about 6000 Å/min or higher, about 6100 Å/min or higher, about 6200 Å/min or higher, about 6300 Å/min or higher, about 6400 Å/min or higher, about 6500 Å/min or higher, about 6600 Å/min or higher, about 6700 Å/min or higher, about 6800 Å/min or higher, about 6900 Å/min or higher, about 7000 Å/min or higher, about 7200 Å/min or higher, about 7300 Å/min or higher, about 7400 Å/min or higher, about 7500 Å/min or higher, about 7600 Å/min or higher, about 7700 Å/min or higher, about 7800 Å/min or higher, about 7900 Å/min or higher, or about 8000 Å/min or higher.

The polishing composition of the invention desirably exhibits a low removal rate when polishing a substrate comprising silicon nitride according to a method of the invention. For example, when polishing silicon wafers comprising silicon nitride in accordance with an embodiment of the invention, the polishing composition desirably exhibits a silicon nitride removal rate of about 500 Å/min or lower, e.g., 400 Å/min or lower, about 300 Å/min or lower, about 200 Å/min or lower, about 100 Å/min or lower, about 90 Å/min or lower, about 80 Å/min or lower, about 70 Å/min or lower, about 60 Å/min or lower, or about 50 Å/min or lower, about 40 Å/min or lower, about 30 Å/min or lower, about 20 Å/min or lower, about 10 Å/min or lower, about 5 Å/min or lower, about 3 Å/min or lower, or about 1 Å/min or lower. In some embodiments, the polishing composition exhibits a silicon nitride removal rate that is too low to be detected.

The chemical-mechanical polishing composition of the invention can be tailored to provide effective polishing at the desired polishing ranges selective to specific thin layer materials, while at the same time minimizing surface imperfections, defects, corrosion, erosion, and the removal of stop layers. Without wishing to be bound to any particular theory, it is believed that the suitable defect performance is due, at least in part, to a reduction of waste interactions with substrate facilitated by the ceria abrasive particles comprising at least one permanently bound silane comprising at least one moiety of Formula I, as described herein.

The polishing composition and method of the invention are particularly suited for use in conjunction with a chemical-mechanical polishing apparatus. Typically, the apparatus comprises a platen, which, when in use, is in motion and has a velocity that results from orbital, linear, or circular motion, a polishing pad in contact with the platen and moving with the platen when in motion, and a carrier that holds a substrate to be polished by contacting and moving the substrate relative to the surface of the polishing pad. The polishing of the substrate takes place by the substrate being placed in contact with the polishing pad and the polishing composition of the invention, and then the polishing pad moving relative to the substrate, so as to abrade at least a portion of the substrate to polish the substrate.

A substrate can be polished with the polishing composition using any suitable polishing pad (e.g., polishing surface). Suitable polishing pads include, for example, woven and non-woven polishing pads. Moreover, suitable polishing pads can comprise any suitable polymer of varying density, hardness, thickness, compressibility, ability to rebound upon compression, and compression modulus. Suitable polymers include, for example, polyvinylchloride, polyvinylfluoride, nylon, fluorocarbon, polycarbonate, polyester, polyacrylate, polyether, polyethylene, polyamide, polyurethane, polystyrene, polypropylene, coformed products thereof, and mixtures thereof. Soft polyurethane polishing pads are particularly useful in conjunction with the inventive polishing method. Typical pads include but are not limited to SURFIN™ 000, SURFIN™ SSW 1, SPM3100 (commercially available from, for example, Eminess Technologies), POLITEX™, NEXPLANAR® E6088 (Entegris Corporation), and Fujibo POLYPAS™ 27. A preferred polishing pad is the EPIC™ D100 pad commercially available from Entegris Corporation.

Desirably, the chemical-mechanical polishing apparatus further comprises an in situ polishing endpoint detection system, many of which are known in the art. Techniques for inspecting and monitoring the polishing process by analyzing light or other radiation reflected from a surface of the substrate being polished are known in the art. Such methods are described, for example, in U.S. Pat. Nos. 5,196,353, 5,433,651, 5,609,511, 5,643,046, 5,658,183, 5,730,642, 5,838,447, 5,872,633, 5,893,796, 5,949,927, and 5,964,643. Desirably, the inspection or monitoring of the progress of the polishing process with respect to a substrate being polished enables the determination of the polishing end-point, i.e., the determination of when to terminate the polishing process with respect to a particular substrate.

Desirably, the inventive polishing composition exhibits a useful removal rate when used to polish layers of silicon oxide while exhibiting a lower removal rate and a greater selectivity for polishing silicon oxide versus silicon nitride, as compared with polishing compositions containing unmodified ceria abrasive particles. The inventive polishing composition further desirably exhibits lower defectivity, for example, producing fewer surface scratches, as compared with polishing compositions containing unmodified ceria abrasive particles. In addition, in some embodiments, the inventive polishing compositions have improved colloidal stability and particle size stability compared with prior art polishing compositions.

### EMBODIMENTS

(1) In embodiment (1) is presented chemical-mechanical polishing composition comprising:
   (i) ceria abrasive particles, wherein the ceria abrasive particles comprise at least one associated silane comprising at least one moiety of Formula I:

Si(R¹)ₙ(X)₍₄₋ₙ₎ (Formula I),
wherein each R¹ is the same or different and is independently selected from a cationic group,
wherein each X is the same or different and is any oxygen containing substituent, wherein at least one X is associated with a surface atom of the ceria abrasive particle
wherein n is 1, 2, or 3, and
(ii) water,
wherein the polishing composition comprises about 0.0005 wt. % to about 25 wt. % of ceria abrasive particles.
(2) In embodiment (2) is presented the polishing composition of embodiment (1), wherein the silane has a molecular weight of about 1500 Daltons or less.
(3) In embodiment (3) is presented the polishing composition of embodiment (1) or (2), wherein the ceria abrasive particles have an average number of silicon atoms per nm² of ceria particles of about 0.08 atoms per nm² to about 5 atoms per nm².
(4) In embodiment (4) is presented the polishing composition of embodiment (3), wherein the ceria abrasive particles have an average number of silicon atoms per nm² of ceria particles of about 0.2 atoms per nm² to about 0.8 atoms per nm².
(5) In embodiment (5) is presented the polishing composition of any one of embodiments (1)-(4), wherein at least one X is —O-G- and G is a surface ceria atom.
(6) In embodiment (6) is presented he polishing composition of any one of embodiments (1)-(5), wherein at least one R¹ is a cationic group, and wherein the cationic group is selected from (3-Aminopropyl)trialkoxysilane, bis(Trialkoxysilylpropyl)amine, 3-trialkoxysilylpropyl)diethylenetriamine, 3-(N-cyclohexylamino)propyltrialkoxysilane, N-Phenyl-gamma-aminopropyltrialkoxysilane, trialkoxysilylpropyl (polyethyleneimine), Aminoethylaminomethyl) phenethyltrialkoxysilane, N-(2-aminoethyl)-3-aminopropyltrialkoxysilane, N-(6-aminohexyl)aminoethyltrialkoxysilane, Bis(2-hydroxyethyl)aminopropyltrialkoxysilane, N-Butylaminopropyltrialkoxysilane, (N,N-Dimethylaminopropyl)trialkoxysilane, N(aminoethyl)aminopropyltrialkoxysilane, N-[3-(Trialkoxysilyl)propyl]-N,N,N-trialkylammonium halide, 2-(4-pyridylethyl)trialkoxysilane, allylamine N-propyltrialkoxysilylallylamine copolymer, and combinations thereof.
(7) In embodiment (7) is presented the polishing composition of any one of embodiments (1)-(6), wherein R¹ is a cationic group, and wherein the cationic group is selected from a 3-(trialkoxysilylpropyl)diethylenetriamine, N-[3-(Trialkoxysilyl) propyl]-N,N,N-trimethylammonium chloride, 3-(N-cyclohexylamino)propyltrialkoxysilane, allylamine N-propyltrialkoxysilylallylamine copolymer, and combinations thereof.
(8) In embodiment (8) is presented the polishing composition of any one of embodiments (1)-(7), wherein the associated silane is derived from a 3-(trimethoxysilylpropyl)diethylenetriamine, N-[3-(Trimethoxysilyl)propyl]-N,N,N-trimethylammonium chloride, 3-(N-cyclohexylamino)propyltrimethoxysilane, allylamine N-propyltriethoxysilylallylamine copolymer, and combinations thereof.
(9) In embodiment (9) is presented the polishing composition of any one of embodiments (1)-(8), wherein at least one X is derived from a chloro, bromo, hydroxy, methoxy, ethoxy, propoxy, butoxy, and combinations thereof.
(10) In embodiment (10) is presented the polishing composition of any one of embodiments (1)-(9), wherein the ceria abrasive particles are selected from wet-process ceria, calcined ceria, and combinations thereof.
(11) In embodiment (11) is presented the polishing composition of any one of embodiments (1)-(10), wherein the polishing composition has a zeta potential greater than about 20 mV at a pH of 3 to 6 or a zeta potential greater than about 10 mV at a pH of 6 to 8.
(12) In embodiment (12) is presented the polishing composition of any one of embodiments (1)-(19), wherein the pH of the polishing composition is about 3 to about 8.
(13) In embodiment (13) is presented the polishing composition of any one of embodiments (1)-(10) and (12), wherein the pH of the polishing composition is about 5 to about 10.
(14) In embodiment (14) is presented the polishing composition of any one of embodiments (1)-(13), wherein the ceria abrasive particles are present in the polishing composition at a concentration of at least about 0.1 wt. %.
(15) In embodiment (15) is presented the polishing composition of any one of embodiments (1)-(14), wherein the ceria abrasive particles are present in the composition at a concentration of about 20 wt. % or less.
(16) In embodiment (16) is presented the polishing composition of any one of embodiments (1)-(15), wherein the polishing composition further comprises an additive selected from a buffer, a surfactant, a catalyst, a stabilizer, a corrosion inhibitor, a biocide, and combinations thereof.
(17) In embodiment (17) is presented a method of chemically mechanically polishing a substrate comprising:
   (a) providing a substrate,
   (b) providing a polishing pad,
   (c) providing a chemical-mechanical polishing composition comprising:
      (i) ceria abrasive particles, wherein the ceria abrasive particles comprise at least one associated silane comprising at least one moiety of Formula I:

Si(R¹)ₙ(X)₍₄₋ₙ₎ (Formula I),
wherein each R¹ is the same or different and is independently selected from a cationic group,
wherein each X is the same or different and is any substituent, and —O-G-, wherein G is a Si of a silicon-containing group or a surface ceria atom of the ceria abrasive particle, and
   wherein n is 1, 2, or 3, and
   (ii) water,
(d) contacting the substrate with the polishing pad and the chemical-mechanical polishing composition, and
(e) moving the polishing pad and the chemical mechanical polishing composition relative to the substrate to abrade at least a portion of the substrate to polish the substrate.
(18) In embodiment (18) is presented the method of embodiment (17), wherein the silane has a molecular weight of about 1500 Daltons or less.
(19) In embodiment (19) is presented the method of embodiment (17) or (18), wherein the ceria abrasive particles have an average number of silicon atoms per nm² of ceria particles of about 0.08 atoms per nm² to about 5 atoms per nm².
(20) In embodiment (20) is presented the method of embodiment (19), wherein the ceria abrasive particles have an average number of silicon atoms per nm² of ceria particles of about 0.2 atoms per nm² to about 0.8 atoms per nm².
(21) In embodiment (21) is presented the method of any one of embodiments (26)-(29), wherein at least one X is-O-G- and G is a surface ceria atom.
(22) In embodiment (22) is presented the method of any one of embodiments (17)-(21), wherein at least one R¹ is a cationic group, and wherein the cationic group is selected from a, and combinations thereof.
(23) In embodiment (23) is presented the method of any one of embodiments (17)-(22), wherein R¹ is a cationic group, and wherein the cationic group is selected from (3-Aminopropyl)trialkoxysilane, bis(Trialkoxysilylpropyl)amine, 3-trialkoxysilylpropyl)diethylenetriamine, 3-(N-cyclohexylamino)propyltrialkoxysilane, N-Phenyl-gamma-aminopropyltrialkoxysilane, trialkoxysilylpropyl (polyethyleneimine), Aminoethylaminomethyl) phenethyltrialkoxysilane, N-(2-aminoethyl)-3-aminopropyltrialkoxysilane, N-(6-aminohexyl)aminoethyltrialkoxysilane, Bis(2-hydroxyethyl)aminopropyltrialkoxysilane, N-Butylaminopropyltrialkoxysilane, (N,N-Dimethylaminopropyl)trialkoxysilane, N(aminoethyl)aminopropyltrialkoxysilane, N-[3-(Trialkoxysilyl)propyl]-N,N,N-trialkylammonium halide, 2-(4-pyridylethyl)trialkoxysilane, allylamine N-propyltrialkoxysilylallylamine copolymer, and combinations thereof.
(24) In embodiment (24) is presented the method of any one of embodiments (17)-(23), wherein the associated silane is derived from 3-(trimethoxysilylpropyl)diethylenetriamine, N-[3-(Trimethoxysilyl)propyl]-N,N,N-trimethylammonium chloride, 3-(N-cyclohexylamino)propyltrimethoxysilane, allylamine N-propyltriethoxysilylallylamine copolymer, and combinations thereof.
(25) In embodiment (25) is presented the method of any one of embodiments (17)-(24), wherein at least one X is derived from a chloro, bromo, hydroxy, methoxy, ethoxy, propoxy, butoxy, and combinations thereof.
(26) In embodiment (43) is presented the method of any one of embodiments (17)-(25), wherein the ceria abrasive particles are selected from wet-process ceria, calcined ceria, and combinations thereof.
(27) In embodiment (27) is presented the method of any one of embodiments (17)-(26), wherein the polishing composition has a zeta potential greater than about 20 mV at a pH of 3 to 6 or a zeta potential greater than about 10 mV at a pH of 6 to 8.
(28) In embodiment (28) is presented the method of any one of embodiments (17)-(27), wherein the pH of the polishing composition is about 3 to about 70. (29) In embodiment (29) is presented the method of any one of embodiments (17)-(27) wherein the pH of the polishing composition is about 5 to about 10.
(30) In embodiment (30) is presented the method of any one of embodiments (17)-(29), wherein the ceria abrasive particles are present in the polishing composition at a concentration of at least about 0.1 wt. %.
(31) In embodiment (31) is presented the method of any one of embodiments (17)-(30), wherein the ceria abrasive particles are present in the composition at a concentration of about 20 wt. % or less.
(32) In embodiment (32) is presented the method of any one of embodiments (17)-(31), wherein the polishing composition further comprises an additive selected from a buffer, a surfactant, a catalyst, a stabilizer, a corrosion inhibitor, a biocide, and combinations thereof.
(33) In embodiment (33) is presented the method of any one of embodiments (17)-(32), wherein the substrate comprises a silicon oxide layer, and wherein at least a portion of the silicon oxide layer is abraded to polish the substrate.
(34) In embodiment (34) is presented he method of any one of embodiments (17)-(33), wherein the polishing composition comprises about 0.0005 wt. % to about 25 wt. % of ceria abrasive particles.

The following examples further illustrate the invention but, of course, should not be construed as in any way limiting its scope.

### Example 1

This example demonstrates cationic silane modification of ceria abrasive particles in accordance with an embodiment of the invention.

Cubiform ceria particles with a size of 140 nm and a surface area of 12 m²/g made by a wet-process method were used in this example. An amount of 1030 g of ceria particles in water (4.54% solids after ion exchange) was mixed with 59 grams of deionized water in a large container. To this mixture was added dropwise, with stirring, over a 30-minute period, 11.35 g of the silane N1-(3-Trimethoxysilylpropyl)diethylenetriamine (Chemical Abstracts Registry No. [35141-30-1]) solution (0.95%). The pH of the mixture was 8.7. The mixture was then transferred to a heated glass reactor and stirred at 75° C. for 24 hours. The particle solution was then allowed to cool and was analyzed. Residual or unreacted silane was removed using ion exchange techniques. The resulting product had a pH of 8.0 and a surface modification of silicon atoms per nm² of ceria particles of 0.38.

### Example 2

This example demonstrates the effect of surface modification of ceria abrasive particles with cationic silanes on oxide and silicon nitride removal rates and surface defectivity achieved with polishing compositions comprising the same, in accordance with an embodiment of the invention.

Separate substrates comprising a blanket layer of silicon oxide (derived from tetraethyl orthosilicate (TEOS) and high-density polysilicon), silicon nitride, and polysilicon were polished with three polishing compositions (Polishing Compositions 2A-2C). Each of the polishing compositions contained 0.2 wt. % of ceria particles in water at a pH adjusted to 4 with acetic acid. Polishing Composition 2A (comparative) contained ceria particles having no surface modification. Polishing Composition 2B and 2C (inventive) contained ceria abrasive particles surface modified with 3-(trimethoxysilylpropyl)diethylenetriamine at two levels (surface modification at a number of silicon atoms per nm² of ceria particles of 1.30 and X).

The substrates were polished using an Mirra™ polishing tool at 2 psi down force, 150 mL/min slurry flow rate, and 100/85 rpm platen speed/head speed with a E6088-24UD pad.

Following polishing, the TEOS removal rates and defects were determined, and the results set forth in Table 1.

TABLE 1
Effect of Cationic Surface Modification of Ceria Abrasive Particles
on Oxide, Silicon Nitride, and Polysilicon Removal Rates

| | | | | | Silicon | Poly |
|---|---|---|---|---|---|---|
| | | Silane | TEOS | HDP | Nitride | Silicon |
| | | Modification | Removal | Removal | Removal | Removal |
| Polishing | | (% surface | Rate | Rate | Rate | Rate |
| Composition | Surface Modification | area) | (Å/min) | (Å/min) | (Å/min) | (Å/min) |
| 2A | None | 0 | 6402 | 4484 | 49 | 466 |
| (comparative) | | | | | | |
| 2B | 3- | 6.1 | 7437 | 5975 | 13 | 1598 |
| (inventive) | (trimethoxysilylpropyl)diethylenetriamine | | | | | |
| | (6.1%) | | | | | |
| 2C | 3- | 12 | 7486 | 6181 | 13 | 1717 |
| (inventive) | (trimethoxysilylpropyl)diethylenetriamine | | | | | |
| | (12%) | | | | | |

As is apparent from the results set forth in Table 1, Polishing Compositions 2B and 2C, which contained ceria particles surface modified with cationic silanes at levels of 6.1 and 12% surface modification respectively, exhibited TEOS, HDP, and polysilicon removal rates that were faster than the removal rates exhibited by Polishing Composition 2A, which did not contain surface modified ceria particles. Polishing Compositions 2B and 2C exhibited lower silicon nitride removal rates than that of Polishing Composition 2A.

### Example 3

This example demonstrates the effect of surface modification of ceria abrasive particles with cationic silanes on TEOS removal rates and patterned wafer topography achieved with polishing compositions comprising the same, in accordance with an embodiment of the invention.

Separate substrates comprising a blanket layer of silicon oxide (derived from tetraethyl orthosilicate (TEOS), and high-density polysilicon (HDP)) and a patterned substrate with a layer of silicon nitride under a layer of HDP oxide were polished with three polishing compositions (Polishing Compositions 3A-3C). Each of the polishing compositions contained 0.2 wt. % of ceria particles in water at a pH adjusted to 4 with acetic acid, and 4.0 mM of glutamic acid. Polishing Composition 3A (comparative) contained ceria particles having no surface modification. Polishing Composition 3B (inventive) contained ceria abrasive particles surface modified with N-[3-(Trimethoxysilyl)propyl]-N,N,N-trimethylammonium chloride (surface modification at a number of silicon atoms per nm² of ceria particles of 1.30). Polishing Composition 3C (inventive) contained ceria particles surface modified with 3-(N-cyclohexylamino)propyltrimethoxysilane (surface modification at a number of silicon atoms per nm² of ceria particles of 1.30). Polishing Composition 3D (inventive) contained ceria particles surface modified with 3-trimethoxysilylpropyl)diethylenetriamine (surface modification at a number of silicon atoms per nm² of ceria particles of 1.30).

The substrates were polished using an Mirra™ polishing tool at 2 psi down force, 150 mL/min slurry flow rate, and 90/83 rpm platen speed/head speed with a E6088-24UD pad.

Following polishing, the TEOS removal rates and defects were determined, and the results set forth in Table 1.

TABLE 2
Effect of Cationionic Surface Modification of Ceria Abrasive
Particles on Oxide Removal Rate and Pattern topography

| | | | | 50 × | |
|---|---|---|---|---|---|
| | | | | 50 μm | |
| | | | | Feature | |
| | | TEOS | HDP | Silicon | 50 × |
| Poli- | | Re- | Re- | Nitride | 50 μm |
| shing | | moval | moval | Re- | Feature |
| Compo- | Surface | Rate | Rate | moval | Dishing |
| sition | Modification | (Å/min) | (Å/min) | (Å) | (Å) |
| 3A | None | 6127 | 5150 | 35 | 1246 |
| (compar- | | | | | |
| ative) | | | | | |
| 3B | N-[3-(Trimethoxy- | 6376 | 5380 | 29 | 1158 |
| (inven- | silyl)propyl]-N,N,N- | | | | |
| tive) | trimethylammonium | | | | |
| | chloride - (12%) | | | | |
| 3C | 3-(N-cyclohexyl- | 6383 | 5385 | 30 | 961 |
| (inven- | amino)propyltrimeth- | | | | |
| tive) | oxysilane - (10%) | | | | |
| 3D | 3-(trimethoxy- | 6416 | 5404 | 32 | 1153 |
| (inven- | silylpropyl)diethylene- | | | | |
| tive) | triamine - (14.2%) | | | | |

As is apparent from the results set forth in Table 2, Polishing Compositions 3B, 3C, and 3D, which contained ceria particles surface modified with cationic silanes, exhibited TEOS and HDP removal rates that were faster to removal rate exhibited by Polishing Composition 3A, which did not contain surface modified ceria particles. Polishing Compositions 3B, 3C, and 3D exhibited lower pattern silicon nitride removal and lower dishing of HDP oxide than that exhibited by comparative Polishing Composition 3A.

### Example 4

This example demonstrates the effect of surface modification of ceria abrasive particles with cationic silanes on TEOS removal rates and patterned wafer topography achieved with polishing compositions comprising the same, in accordance with an embodiment of the invention.

Separate substrates comprising a blanket layer of silicon oxide (derived from tetraethyl orthosilicate (TEOS)), silicon nitride, and polysilicon were polished with three polishing compositions (Polishing Compositions 4A-4C). Each of the polishing compositions contained 0.2 wt. % of ceria particles in water at a pH adjusted to 4 with acetic acid. Polishing Composition 4A (comparative) contained ceria particles having no surface modification. Polishing Composition 4B and 4C (inventive) contained ceria abrasive particles surface modified with allylamine N-propyltriethoxysilylallylamine copolymer at two levels (surface modification at a number of silicon atoms per nm² of ceria particles of 1.30 and X).

The substrates were polished using an Mirra™ polishing tool at 3 psi down force, 150 mL/min slurry flow rate, and 100/85 rpm platen speed/head speed with a E6088-24UD pad.

TABLE 3
Effect of Cationic Surface Modification of Ceria Abrasive Particles
on Oxide, Silicon Nitride, and Polysilicon Removal Rates

| | | Silane | | Silicon | Poly |
|---|---|---|---|---|---|
| | | Modifi- | TEOS | Nitride | Silicon |
| Poli- | | cation | Re- | Re- | Re- |
| shing | | (% | moval | moval | moval |
| Compo- | Surface | surface | Rate | Rate | Rate |
| sition | Modification | area) | (Å/min) | (Å/min) | (Å/min) |
| 4A | None | 0 | 6865 | 19 | 420 |
| (compar- | | | | | |
| ative) | | | | | |
| 4B | allylamine N- | 2.5 | 7048 | 18 | 564 |
| (inven- | propyltriethoxy- | | | | |
| tive) | silylallylamine | | | | |
| | copolymer | | | | |
| 4C | allylamine N- | 5 | 2903 | 20 | 534 |
| (inven- | propyltriethoxy- | | | | |
| tive) | silylallylamine | | | | |
| | copolymer | | | | |

As is apparent from the results set forth in Table 3, Polishing Composition 4B and, which contained ceria particles surface modified with cationic silanes at 2.5% surface modification, exhibited TEOS, and polysilicon removal rates that were faster than the removal rates exhibited by Polishing Composition 4A, which did not contain surface modified ceria particles. Polishing Compositions 4C, which was modified with 5% cationic silane surface modification, exhibited lower silicon nitride removal rates than that of Polishing Composition 4A and 4B but higher polysilicon removal rate. All silicon nitride rates were similar for compositions 4A-4C.

### Example 5

This example demonstrates the effect of surface modification of ceria abrasive particles with cationic silanes on colloidal stability over aging time with polishing compositions comprising the same, in accordance with an embodiment of the invention.

Separate polishing compositions were prepared containing 0.28 wt. % of ceria particles in water and 500 ppm picolinic acid at a pH adjusted to 4 with acetic acid. The polishing compositions were then combined with a separate composition solution consisting of 4000 ppm BIS-TRIS, 20 ppm diallyldimethylammonium chloride, 330 ppm polyvinylpropylene K-12, 1670 ppm benzhydroxamic acid, and 30 ppm of Kordek MLX adjusted to pH 4.0 with acetic acid. Upon combination, the final pH of the solutions were pH 4.0. The combined polishing composition and solution were then measured at initial time of combination and allowed to age for 48 hours. The particle size within each combined solution was then measured using a Malvern particle sizing instrument at initial time of mixing and at 48 hours.

Table 4 shows the average particle size of the mixtures with a monomodal distribution at time=0 and a bimodal distribution at time=48 hours. Table 4 identifies the change in peak position with aging time along with the growth of a secondary particle size peak. Those skilled in the art will understand that peak position change and a measure called peak width at half height describes how much a particle does or does not grow over time. As table 4 describes, the inventive composition 4B shows a resistance to the shift in peak 2 at 298 nm particle size vs. comparisons at much larger of 769 and 672 nm. Further, the peak width at half height is much smaller at 3.804 for the inventive 4B composition vs. comparatives at 13.472 nm and 7.660 nm. This data shows that increased colloidal stability is achieved with the inventive composition of 4B vs. base ceria particle and comparative particle treatment.

TABLE 4
Effect of Cationic Surface Modification of Ceria Abrasive Particles
on Colloidal Stability Through the Prevention of Particle Growth

| | | | Peak 1 | Peak 1 | Peak 2 |
|---|---|---|---|---|---|
| | | | Day 1 | Day 2 | Day 2 |
| | | Silane | (Peak | (Peak | (Peak |
| | | Modifi- | position, | position, | position, |
| Poli- | | cation | Peak | Peak | Peak |
| shing | | (% | width | width | width |
| Compo- | Surface | surface | at half | at half | at half |
| sition | Modification | area) | height) | height) | height) |
| 4A | None | 0 | 87 nm, 64 | 150 nm, | 769 nm, |
| (compar- | | | nm | 0.097 nm | 13.472 nm |
| ative) | | | | | |
| 4B | 3-(trimethoxy- | 8 | 87 nm, 64 | 150 nm, | 298 nm, |
| (inven- | silylpropyl) | | nm | 0.083 nm | 3.804 nm |
| tive) | diethylenetri- | | | | |
| | amine | | | | |
| 4C | Aminopropyl- | 8 | 87 nm, 64 | 150 nm, | 672 nm, |
| (compar- | trimethoxy- | | nm | 0.111 nm | 7.660 nm |
| ative) | silane | | | | |

1. A chemical-mechanical polishing composition comprising:
(i) ceria abrasive particles, wherein the ceria abrasive particles comprise at least one associated silane comprising at least one moiety of Formula I:
Si(R¹)ₙ(X)₍₄₋ₙ₎ (Formula I),
wherein each R¹ is the same or different and is independently selected from a cationic group,
wherein each X is the same or different and is any oxygen containing substituent, wherein at least one X is associated with a surface atom of the ceria abrasive particle, and
wherein n is 1, 2, or 3, and
(ii) water,
wherein the polishing composition comprises about 0.0005 wt. % to about 25 wt. % of ceria abrasive particles.

2. The polishing composition of claim 1, wherein the silane has a molecular weight of about 1500 Daltons or less.

3. The polishing composition of claim 1, wherein the ceria abrasive particles have an average number of silicon atoms per nm² of ceria particles of about 0.08 atoms per nm² to about 5 atoms per nm².

4. The polishing composition of claim 3, wherein the ceria abrasive particles have an average number of silicon atoms per nm² of ceria particles of about 0.2 atoms per nm² to about 0.8 atoms per nm².

5. The polishing composition of any one of claim 1, wherein at least one X is —O-G- and G is a surface ceria atom.

6. The polishing composition of any one of claim 1, wherein at least one R¹ is a cationic group, and wherein the cationic group is selected from an amine (primary, secondary, tertiary, and quaternary), monoamine, diamine, triamine, polyamine, pyridinium, and combinations thereof.

7. The polishing composition of any one of claim 1, wherein R¹ is a cationic group, and wherein the cationic group is selected from (3-Aminopropyl)trialkoxysilane, bis(Trialkoxysilylpropyl)amine, 3-trialkoxysilylpropyl)diethylenetriamine, 3-(N-cyclohexylamino)propyltrialkoxysilane, N-Phenyl-gamma-aminopropyltrialkoxysilane, trialkoxysilylpropyl (polyethyleneimine), Aminoethylaminomethyl) phenethyltrialkoxysilane, N-(2-aminoethyl)-3-aminopropyltrialkoxysilane, N-(6-aminohexyl)aminoethyltrialkoxysilane, Bis(2-hydroxyethyl)aminopropyltrialkoxysilane, N-Butylaminopropyltrialkoxysilane, (N,N-Dimethylaminopropyl)trialkoxysilane, N(aminoethyl)aminopropyltrialkoxysilane, N-[3-(Trialkoxysilyl)propyl]-N,N,N-trialkylammonium halide, 2-(4-pyridylethyl)trialkoxysilane, allylamine N-propyltrialkoxysilylallylamine copolymer, and combinations thereof.

8. The polishing composition of any one of claim 1, wherein the associated silane is derived from 3-(trimethoxysilylpropyl)diethylenetriamine, N-[3-(Trimethoxysilyl) propyl]-N,N,N-trimethylammonium chloride, 3-(N-cyclohexylamino)propyltrimethoxysilane, allylamine N-propyltriethoxysilylallylamine copolymer, and combinations thereof.

9. The polishing composition of any one of claim 1, wherein at least one X is derived from a chloro, bromo, hydroxy, methoxy, ethoxy, propoxy, butoxy, and combinations thereof.

10. The polishing composition of claim 1, wherein the polishing composition has a zeta potential greater than about 20 mV at a pH of 3 to 6 or a zeta potential greater than about 10 mV at a pH of 6 to 8.

11. The polishing composition of claim 1, wherein the ceria abrasive particles are present in the polishing composition at a concentration of at least about 0.1 wt. % to about 20 wt. % or less.

12. The polishing composition of claim 1, wherein the polishing composition further comprises an additive selected from a buffer, a surfactant, a catalyst, a stabilizer, a corrosion inhibitor, a biocide, and combinations thereof.

13. A method of chemically mechanically polishing a substrate comprising:
(a) providing a substrate,
(b) providing a polishing pad,
(c) providing a chemical-mechanical polishing composition comprising:
(i) ceria abrasive particles, wherein the ceria abrasive particles comprise at least one associated silane comprising at least one moiety of Formula I:
Si(R¹)ₙ(X)₍₄₋ₙ₎ (Formula I),
wherein each R¹ is the same or different and is independently selected from a cationic group,
wherein each X is the same or different and is any oxygen containing substituent, wherein at least one X is associated with a surface atom of the ceria abrasive particle, and
wherein n is 1, 2, or 3, and
(ii) water,
(d) contacting the substrate with the polishing pad and the chemical-mechanical polishing composition, and
(e) moving the polishing pad and the chemical mechanical polishing composition relative to the substrate to abrade at least a portion of the substrate to polish the substrate.

14. The method of claim 13, wherein the silane has a molecular weight of about 1500 Daltons or less.

15. The method of claim 13, wherein the ceria abrasive particles have an average number of silicon atoms per nm² of ceria particles of about 0.08 atoms per nm² to about 5 atoms per nm².

16. The method of claim 13, wherein at least one X is —O-G- and G is a surface ceria atom.

17. The method of claim 13, wherein at least one R¹ is a cationic group, and wherein the cationic group is selected from an amine (primary, secondary, tertiary, and quaternary), monoamine, diamine, triamine, polyamine, pyridinium, and combinations thereof.

18. The method of claim 13, wherein R¹ is a cationic group, and wherein the cationic group is selected from (3-Aminopropyl)trialkoxysilane, bis(Trialkoxysilylpropyl)amine, 3-trialkoxysilylpropyl)diethylenetriamine, 3-(N-cyclohexylamino)propyltrialkoxysilane, N-Phenyl-gamma-aminopropyltrialkoxysilane, trialkoxysilylpropyl (polyethyleneimine), Aminoethylaminomethyl) phenethyltrialkoxysilane, N-(2-aminoethyl)-3-aminopropyltrialkoxysilane, N-(6-aminohexyl)aminoethyltrialkoxysilane, Bis(2-hydroxyethyl)aminopropyltrialkoxysilane, N-Butylaminopropyltrialkoxysilane, (N,N-Dimethylaminopropyl)trialkoxysilane, N(aminoethyl)aminopropyltrialkoxysilane, N-[3-(Trialkoxysilyl)propyl]-N,N,N-trialkylammonium halide, 2-(4-pyridylethyl)trialkoxysilane, allylamine N-propyltrialkoxysilylallylamine copolymer, and combinations thereof.

19. The method of claim 13, wherein the polishing composition has a zeta potential greater than about 20 mV at a pH of 3 to 6 or a zeta potential greater than about 10 mV at a pH of 6 to 8.

20. The method of claim 13, wherein the substrate comprises a silicon oxide layer, and wherein at least a portion of the silicon oxide layer is abraded to polish the substrate.
